(19) United States
(12) Patent Application Publication
(10) Pub. No.: US 2016/0302315 A1
(43) Pub. Date: Oct. 13, 2016

(54) DISPLAY APPARATUS HAVING A VARYING VIEWING DISTANCE

(71) Applicant: SAMSUNG DISPLAY CO., LTD., Yongin-City (KR)

(72) Inventors: BYEONGHWA CHOI, Yongin-City (KR); SEUNGBAE LEE, Yongin-City (KR)

(21) Appl. No.: 14/925,762

(22) Filed: Oct. 28, 2015

(30) Foreign Application Priority Data
Apr. 9, 2015 (KR) 10-2015-0050241

(51) Int. Cl. H05K 5/02; H05K 5/00

(52) U.S. Cl. CPC H05K 5/0217; H05K 5/0017; H05K 5/0234

(57) ABSTRACT

A display apparatus includes a support plate. A connection member is disposed on the support plate, the connection member having a first end portion connected to the support plate. A display unit is connected to a second end portion of the connection member and displays images. The support plate is configured to rotate about a first axis.

### RELATED APPLICATION

This application claims priority under 35 U.S.C. § 119 to Korean Patent Application No. 10-2015-0050241, filed on Apr. 9, 2015, in the Korean Intellectual Property Office, the disclosure of which is incorporated by reference herein in its entirety.

### TECHNICAL FIELD

Exemplary embodiments of the present inventive concept relate to a display apparatus. More particularly, exemplary embodiments of the present inventive concept relate to a display apparatus having a varying viewing distance.

### DISCUSSION OF THE RELATED ART

As technology advances, people increasingly use a large variety of display apparatuses such as television systems or computer systems including monitors. Usage time of the display apparatuses increases due to the users' lifestyles.

As the amount of time in which a user spends before a display apparatus increases, the user may experience eye fatigue due to electromagnetic waves generated from the display apparatus, unbalance between the brightness of the display apparatus and the peripheral environment, and display of full-color images. Thus, the eyesight and working efficiency of the user may degrade.

Since such a display apparatus is generally fixed by a stand or fixed on a wall, a visual distance (VD) between a viewer and the display apparatus is fixedly maintained unless the viewer moves. In this case, the viewer watches the display apparatus for a long time at a constant distance without adjusting the muscles in the lens of the eye, for example, without contracting and relaxing the muscles in the lens of the eye. Thus eye fatigue that the viewer may experience worsens.

### SUMMARY

According to an exemplary embodiment of the present inventive concept, a display apparatus may be capable of adjusting a visual distance (VD).

According to an exemplary embodiment of the present inventive concept, a display apparatus includes a support plate. A connection member is disposed on the support plate, the connection member having a first end portion connected to the support plate. A display unit is connected to a second end portion of the connection member and displays images. The support plate is configured to rotate about a first axis.

In an exemplary embodiment of the present inventive concept, the first axis extends through the support plate.

In an exemplary embodiment of the present inventive concept, the support plate is configured to rotate at least in a clockwise direction or in a counter-clockwise direction about the first axis.

In an exemplary embodiment of the present inventive concept, the connection member is disposed at a first point that is spaced apart from the first axis of the support plate.

In an exemplary embodiment of the present inventive concept, the connection member rotates about a second axis that extends through the connection member on the support plate.

In an exemplary embodiment of the present inventive concept, the connection member is configured to rotate at least in a clockwise direction or in a counter-clockwise direction about the second axis.

In an exemplary embodiment of the present inventive concept, the support plate rotates about the first axis by a first angle to move the connection member and the display unit from a first position to a second position, and the connection member rotates about the second axis by a second angle.

In an exemplary embodiment of the present inventive concept, the second angle depends on the first angle.

In an exemplary embodiment of the present inventive concept, the display unit comprises a screen fixed at the second end portion of the connection member for displaying images. A first direction in which the screen is oriented at the first position is substantially parallel to a second direction in which the screen is oriented at the second position due to the rotation of the connection member.

In an exemplary embodiment of the present inventive concept, the display unit includes a liquid crystal display (LCD) panel or an organic light-emitting diode (OLED) display panel.

According to an exemplary embodiment of the present inventive concept, a display apparatus includes a support plate configured to rotate in a first rotation direction. A connection member is disposed on the support plate, the connection member having a first end portion connected to the support plate, and wherein the connection member is configured to rotate in a second rotation direction opposite to the first rotation direction. A display unit is connected to a second end portion of the connection member. The display unit maintains an initial alignment when the support plate rotates in the first rotation direction.

In an exemplary embodiment of the present inventive concept, the support plate rotates about a first axis, the connection member rotates about a second axis, and the first and second axes are substantially parallel with respect to each other.

In an exemplary embodiment of the present inventive concept, a display apparatus further includes a first gear disposed under the support plate and a second gear engaged to the first gear. The first gear rotates about the first axis. The second gear rotates about a third axis. The first and third axes are substantially parallel with respect to each other.

In an exemplary embodiment of the present inventive concept, the support plate forms a plane, and wherein a long axis of the connection member is substantially perpendicular to the plane.

In an exemplary embodiment of the present inventive concept, when the support plate moves from a first position to a second position by rotating in the first rotation direction by a first angle, the connection member rotates about the second rotation direction by a second angle. The first and second angles are equal in magnitude.

In an exemplary embodiment of the present inventive concept, the display unit includes a display screen, wherein the display screen is aligned along a first direction in the first position, wherein the display screen is aligned along a second direction in the second position, and wherein the first and second directions are substantially parallel with respect to each other.

In an exemplary embodiment of the present inventive concept, a display further includes a third gear under the support plate and a fourth gear engaged to the third gear.

The third gear is configured to rotate about a fourth axis, and the fourth axis corresponds to an axis in which the support plate is configured to rotate around. The support plate moves from a third position to a fourth position when rotating the third gear about the fourth axis by a fourth angle. The fourth gear rotates about a fifth axis by a fifth angle, and the fourth gear is fixed to the connection member.

In an exemplary embodiment of the present inventive concept, the fourth angle is substantially equal to the fifth angle.

In an exemplary embodiment of the present inventive concept, the display unit includes a display screen, and a third direction in which the display screen is oriented at the third position is substantially parallel to a fourth direction in which the display screen is oriented at the fourth position.

According to an exemplary embodiment of the present inventive concept, the display apparatus includes a plate. A connection member is disposed on the plate, the connection member having a first end connected to the plate. A display device is disposed in a second end of the connection member. The plate forms a plane and is configured to rotate around a first axis in a first direction on the plane, and the first axis is substantially perpendicular to the plane. The connection member is configured to rotate in a second direction around a second axis, the second direction is different from the first direction, and the second axis is substantially parallel to the first axis. The display device is configured to face a viewer at substantially the same direction when the plate rotates in the first direction.

### BRIEF DESCRIPTION OF THE DRAWINGS

The above and other features and/or aspects of the present inventive concept will become more apparent and more readily appreciated from the following description of the exemplary embodiments thereof taken in conjunction with the accompanying drawings in which:

FIG. 1 is a schematic diagram of a display apparatus according to an exemplary embodiment of the present inventive concept;

FIG. 2 is a diagram of the display apparatus of FIG. 1 in which a connection member and a display unit are moved from a first position to a second position by a rotation of a support plate, according to an exemplary embodiment of the present inventive concept;

FIGS. 3A and 3B are diagrams showing variation in a visual distance (VD) between a viewer and the display unit of the display apparatus, of FIG. 1, according to an exemplary embodiment of the present inventive concept;

FIG. 4 is a diagram of the support plate and a connection unit of the display apparatus of FIG. 1 according to an exemplary embodiment of the present inventive concept; and

FIG. 5 is a diagram of the support plate and the connection unit of the display apparatus of FIG. 1 according to an exemplary embodiment of the present inventive concept.

### DETAILED DESCRIPTION OF THE EMBODIMENTS

Exemplary embodiments of the present inventive concept will be illustrated in detail with reference to the accompanying drawings. Various changes may be made to the disclosed embodiments without departing from the scope of the present inventive concept. Thus, the present inventive concept is not limited to the disclosed exemplary embodiments thereof and may include changes made thereto.

Like reference numerals in the drawings may refer to like elements throughout the specification and the figures.

As used herein, the singular forms “a,” “an” and “the” are intended to include the plural forms as well, unless the context clearly indicates otherwise.

It will be understood that when a layer, region, or component is referred to as being “formed on” another layer, region, or component, it may be formed on the other layer, region, or component, or intervening layers, regions, or components may be present.

Sizes of components in the drawings may be exaggerated for convenience of explanation. Since sizes and thicknesses of components in the drawings may be arbitrarily illustrated for convenience of explanation, the exemplary embodiments of the present inventive concept are not limited thereto.

It will be understood that when a layer, region, or component is referred to as being connected to another layer, region, or component, it may be connected to the other layer, region, or component, or intervening layers, regions, or components may be present. As used herein, the term “and/or” may include any and all combinations of one or more of the associated listed items.

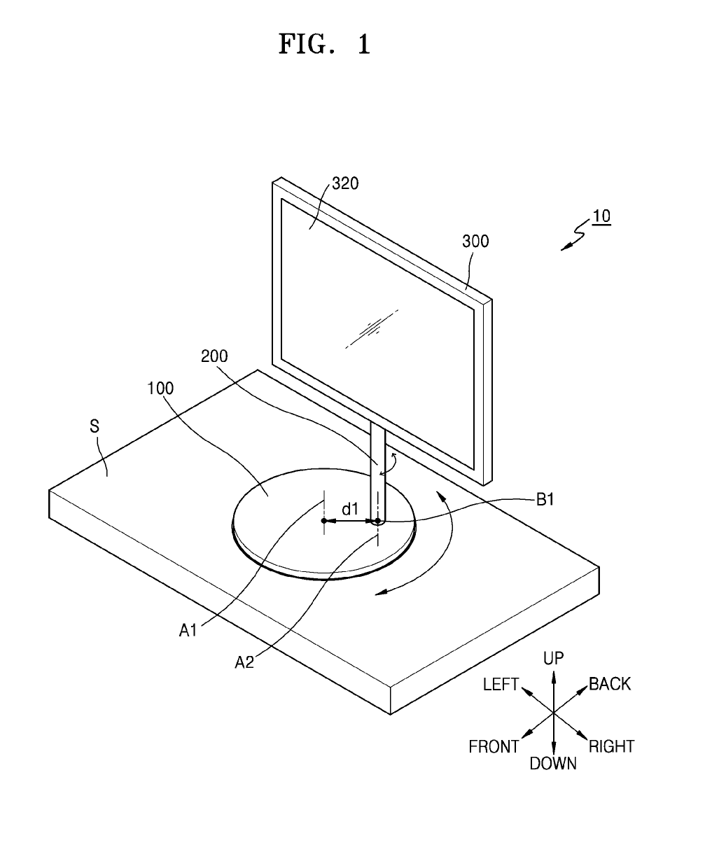

FIG. 1 is a schematic diagram of a display apparatus 10 according to an exemplary embodiment of the present inventive concept.

Referring to FIG. 1, the display apparatus 10, according to an exemplary embodiment of the present inventive concept, may include a support plate 100, a connection member 200, and a display unit 300.

The support plate 100 may be formed as a rotatable plate and may be located on a stand S on which the display apparatus 10 may be provided. The support plate 100 may rotate in a clockwise direction or a counter-clockwise direction about a first axis Al that extends through the support plate 100. In FIG. 1, the support plate 100 is located on the stand S. However, the present inventive concept is not limited thereto. For example, in an exemplary embodiment of the present inventive concept, the support plate 100 may be disposed in the stand S or may constitute a part of the stand S.

The connection member 200 may have a first end portion connected to the support plate 100 and a second end portion connected to the display unit 300. The connection member 200 may extend along a direction that is perpendicular to a plane formed by the support plate 100.

The connection member 200 may be disposed on a first point B1 on the support plate 100. The first point B1 may be separated by a first distance d1 from the first axis A1 of the support plate 100. When the support plate 100 rotates about the first axis A1, the location of the connection member 200 on the support plate 100 may be changed by making a circular movement having the first distance d1 from the first axis A1 as a radius. The location of the display unit 300 connected to the second end portion of the connection member 200 may also be changed.

The connection member 200 may rotate in the clockwise direction or the counter-clockwise direction about a second axis A2 that extends through the connection member 200 on the support plate 100.

In FIG. 1, the connection member 200 is formed as a bar having a predetermined height. The connection member 200 may be coupled to the inside of the display unit 300.

The display unit 300 may include a screen 320 for displaying images. The screen 320 may be a liquid crystal display (LCD) panel or an organic light-emitting diode (OLED) display panel.

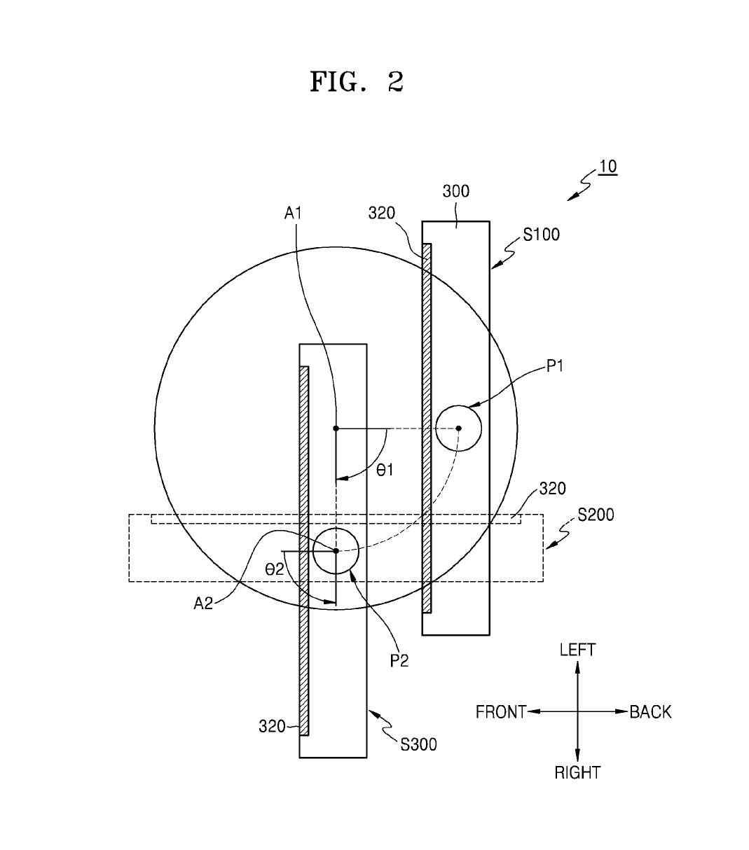

FIG. 2 is a diagram of the display apparatus 10 of FIG. 1 in which the connection member 200 and the display unit 300 are moved from a first position P1 to a second position P2 by a rotation of the support plate 100.

Referring to FIG. 2, the display unit 300 may be exposed toward a front of the display apparatus 10 at the first position P1 to display images toward the front of the display apparatus 10 (e.g., in an S100 position).

When the support plate 100 rotates by a first angle 01 in the clockwise direction (or the counter-clockwise direction), the connection member 200 and the display unit 300 that is fixedly connected to the second end portion of the connection member 200 may be moved to the second position P2 because the first end portion of the connection member 200 is connected to the support plate 100 (e.g., in an 5200 position). Here, when the connection member 200 does not rotate about the second axis A2, the screen 320 might not face the front of the display apparatus 10 and the image displayed on the screen 320 might not be seen by a viewer.

However, according to one or more exemplary embodiments of the present inventive concept, when the connection member 200 rotates by a second angle 02 about the second axis A2, the display unit 300 connected to the second end portion of the connection member 200 may also rotate by the second angle 02. Therefore, the screen 320 of the display unit 300 may be directed toward the front of the display apparatus 10 (e.g., in an S300 position).

When the support plate 100 rotates about the first axis A1, the connection member 200 and the display unit 300 may be moved from the first position P1 to the second position P2, and the distance between a viewer and the display unit 300 may vary. Since the distance between the viewer and the display unit 300 (e.g., a visual distance (VD)) varies, muscles that adjust the thickness of the lens of the eye of the viewer move. Thus, eye fatigue that the viewer may experience may be reduced due to the movement of the muscles that adjust the thickness of the human eye lens.

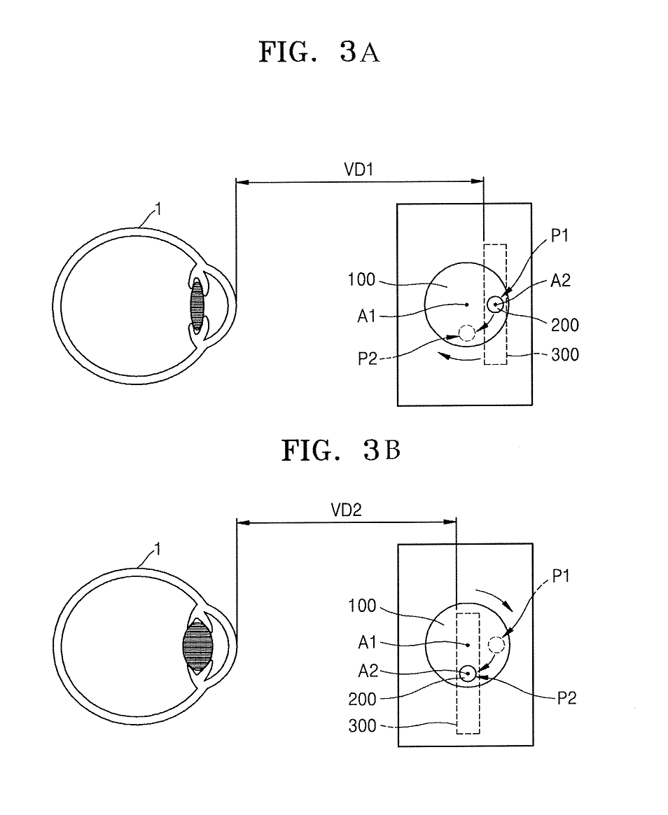

FIGS. 3A and 3B are diagrams showing the variation in the VD between the viewer and the display unit 300 of to the display apparatus 10 of FIG. 1, according to an exemplary embodiment of the present inventive concept.

FIG. 3A shows a first visual distance (VD1) at the first position P1, and FIG. 3B shows a second visual distance (VD2) at the second position P2. In FIGS. 3A and 3B, the display unit 300 is denoted by dashed lines for convenience of description.

Referring to FIGS. 3A and 3B, the support plate 100 may rotate in the clockwise direction (or the counter-clockwise direction) about the first axis A1, as described above with reference to FIG. 2. The locations of the connection member 200 and the display unit 300 may be changed from the first position P1 to the second position P2.

At the second position P2, the VD2 between a viewer 1 and the display unit 300 may be shorter than the VD1 between the viewer 1 and the display unit 300 at the first position P1. Since the display unit 300 moves from the first position P1 to the second position P2, the VD may vary. Thus, eye fatigue that the viewer 1 may experience may be reduced.

The VD may be the shortest when the support plate 100 rotates by 180° from the first position P1 and may then increase when the support plate 100 continues to rotate in the clockwise direction (or the counter-clockwise direction). The VD between the viewer 1 and the display unit 300 may be adjusted according to the first angle θ1 that is the rotation angle of the support plate 100.

In the display apparatus 10, according to an exemplary embodiment of the present inventive concept, since the connection member 200 rotates by the second angle θ2 about the second axis A2 while the support plate 100 rotates by the first angle θ1 about the first axis A1, the screen 320 of the display unit 300 may be continuously directed toward the front of the display apparatus 10. Thus, the screen 320 of the display unit 300 may continuously face the viewer 1.

The second angle θ2 may be dependent upon the first angle θ1. For example, if the support plate 100 is rotated by the first angle θ1 about the first axis A1, the second angle θ2 may be equal to the first angle θ1 or may have a value obtained by subtracting the first angle θ1 from 360° (e.g., 360°-θ1), according to the rotating direction. Therefore, the screen 320 may be continuously directed toward the viewer 1.

According to an exemplary embodiment of the present inventive concept, when the support plate 100 is rotated by the first angle θ1 in the clockwise direction about the first axis A1, the connection member 200 may rotate by the second angle θ2 that is equal to the first angle θ1 in the counter-clockwise direction. According to an exemplary embodiment of the present inventive concept, when the support plate 100 is rotated by the first angle θ1 in the counter-clockwise direction about the first axis A1, the connection member 200 may rotate by the second angle θ2 that is equal to the first angle θ1 in the clockwise direction. For example, when the support plate 100 rotates in the clockwise direction or the counter-clockwise direction, the connection member 200 may rotate in a direction that is opposite to the rotation direction of the support plate 100.

A method of driving the display apparatus 10 will be described according to an exemplary embodiment of the present inventive concept.

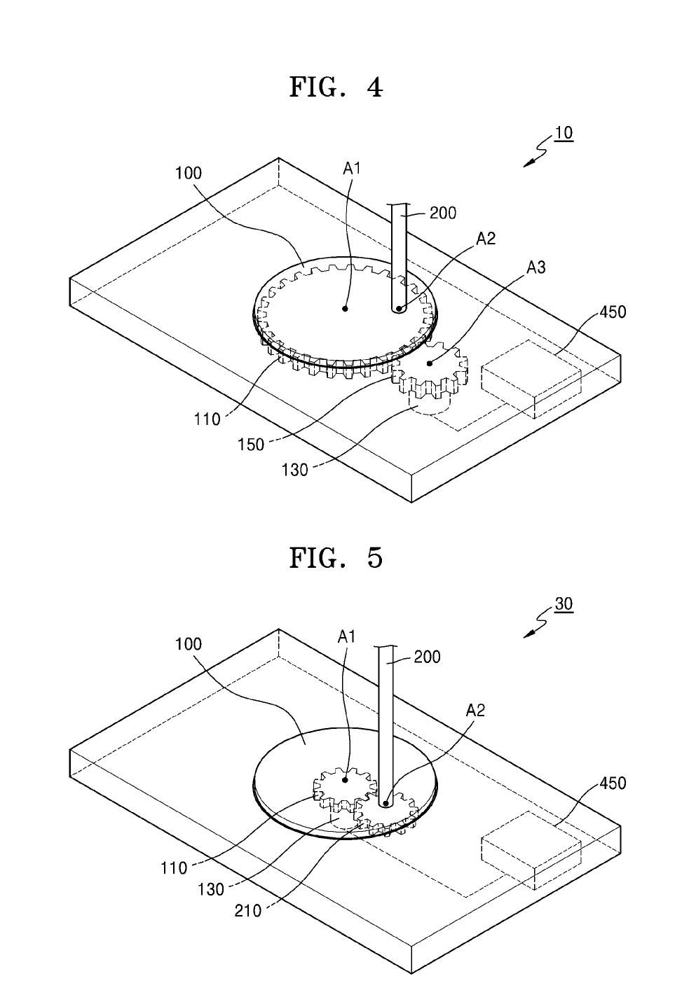

FIG. 4 is a diagram of the support plate 100 and the connection member 200 of the display apparatus 10, according to an exemplary embodiment of the present inventive concept.

Referring to FIG. 4, a first gear portion 110 may be disposed under the support plate 100, and the first gear portion 110 may be engaged with a second gear portion 150.

In an exemplary embodiment of the present inventive concept, the first gear portion 110 may be formed on the support plate 100. However, the present inventive concept is not limited thereto. For example, the support plate 100 may include sawteeth on an outer circumferential surface thereof to perform as both the support plate 100 and the first gear portion 110.

The second gear portion 150 may be connected to a motor 130, and may be engaged with the first gear portion 110. The motor 130 may be disposed coaxially with a third axis A3 that extends through the second gear portion 150, and the second gear portion 150 may be rotated when the motor 130 drives. The first gear portion 110 is rotated according to the rotation of the second gear portion 150 to rotate the support plate 100.

The connection member 200 may include a motor or an actuator therein, and the connection member 200 may be rotated by driving the motor or the actuator.

Rotating speed, rotational period, and rotating direction of the support plate 100 may be controlled according to a selection made by the viewer 1. The connection member 200 may be controlled according to the selection made by the viewer 1. A controller 450 included in the display apparatus 10 may control the operations of the support plate 100 and the connection member 200 according to the user's selection input through an input member such as a remote controller.

The motor 130 may be replaced with a driving apparatus such as an actuator, according to an exemplary embodiment of the present inventive concept. Although not shown in FIG. 4, when the motor 130 is arranged coaxially with the first axis A1 that extends through the support plate 100, the motor 130 may directly rotate the support plate 100 without using the first and second gear portions 110 and 150.

In FIG. 4, the first and second gear portions 110 and 150 may be spur gears. However, exemplary embodiments of the present inventive concept are not limited thereto. Sizes and kinds of the first and second gear portions 110 and 150 may be variously modified.

FIG. 5 is a diagram of the support plate 100 and the connection member 200 of the display apparatus 10, according to an exemplary embodiment of the present inventive concept.

Referring to FIG. 5, the first gear portion 110 may be disposed under the support plate 100, and a third gear portion 210 may be disposed under the connection member 200. In addition, the first gear portion 110 and the third gear portion 210 may be engaged with each other.

The first gear portion 110 may be connected to the motor 130 rotating about the first axis A1 to rotate the support plate 100 connected thereto via the rotational driving of the motor 130. The third gear portion 210 may be rotated according to the rotation of the first gear portion 110, and the connection member 200 may be rotated according to the rotation of the third gear portion 210. The support plate 100 and the connection member 200 may be simultaneously rotated by using the motor 130.

In FIG. 5, the first and third gear portions 110 and 210 may be spur gears. However, exemplary embodiments of the present inventive concept are not limited thereto. Sizes and kinds of the first and third gear portions 110 and 210 may be variously modified.

As described above, according to one or more exemplary embodiments of the present inventive concept, the VD between a display apparatus and a viewer may be adjusted so that the muscles adjusting the thickness of the lens of the eye may repeatedly contract and relax. Thus, eye fatigue that the viewer may experience when focusing on the screen 320 of the display unit 300 may be reduced.

It should be understood that the exemplary embodiments of the present inventive concept described above should be considered in a descriptive sense only and not for purposes of limitation.

While the inventive concept has been particularly shown and described with reference to exemplary embodiments thereof, it will be apparent to those of ordinary skill in the art that various changes in form and detail may be made therein without departing from the spirit and scope of the inventive concept.

What is claimed is:

1. A display apparatus comprising:
a support plate;
a connection member disposed on the support plate, the connection member having a first end portion connected to the support plate; and
a display unit connected to a second end portion of the connection member and displaying images,
wherein the support plate is configured to rotate about a first axis.

2. The display apparatus of claim 1, wherein the first axis extends through the support plate.

3. The display apparatus of claim 1, wherein the support plate is configured to rotate at least in a clockwise direction or in a counter-clockwise direction about the first axis.

4. The display apparatus of claim 1, wherein the connection member is disposed at a first point that is spaced apart from the first axis of the support plate.

5. The display apparatus of claim 1, wherein the connection member rotates about a second axis that extends through the connection member.

6. The display apparatus of claim 5, wherein the connection member is configured to rotate at least in a clockwise direction or in a counter-clockwise direction about the second axis.

7. The display apparatus of claim 5, wherein the support plate rotates about the first axis by a first angle to move the connection member and the display unit from a first position to a second position, and the connection member rotates about the second axis by a second angle.

8. The display apparatus of claim 7, wherein the second angle depends on the first angle.

9. The display apparatus of claim 7, wherein the display unit comprises a screen fixed at the second end portion of the connection member for displaying images, and a first direction in which the screen is oriented at the first position is substantially parallel to a second direction in which the screen is oriented at the second position due to the rotation of the connection member.

10. The display apparatus of claim 1, wherein the display unit comprises a liquid crystal display (LCD) panel or an organic light-emitting diode (OLED) display panel.

11. A display apparatus comprising:
a support plate configured to rotate in a first rotation direction;
a connection member disposed on the support plate, the connection member having a first end portion connected to the support plate, and wherein the connection member is configured to rotate in a second rotation direction opposite to the first rotation direction; and
a display unit connected to a second end portion of the connection member,
wherein the display unit maintains an initial alignment when the support plate rotates in the first rotation direction.

12. The display apparatus of claim 11, wherein the support plate rotates about a first axis, wherein the connection member rotates about a second axis, and wherein the first and second axes are substantially parallel with respect to each other.

13. The display apparatus of claim 12, further comprising a first gear disposed under the support plate and a second gear engaged to the first gear,
wherein the first gear rotates about the first axis,
wherein the second gear rotates about a third axis, and
wherein the first and third axes are substantially parallel with respect to each other.

14. The display apparatus of claim 11, wherein the support plate forms a plane, and wherein a long axis of the connection member is substantially perpendicular to the plane.

15. The display apparatus of claim 11, wherein, when the support plate moves from a first position to a second position by rotating in the first rotation direction by a first angle, the connection member rotates about the second rotation direction by a second angle, and wherein the first and second angles are equal in magnitude.

16. The display apparatus of claim 15, wherein the display unit includes a display screen, wherein the display screen is aligned along a first direction in the first position, wherein the display screen is aligned along a second direction in the second position, and wherein the first and second directions are substantially parallel with respect to each other.

17. The display apparatus of claim 11, further comprising a third gear under the support plate and a fourth gear engaged to the third gear, wherein the third gear is configured to rotate about a fourth axis, and wherein the fourth axis corresponds to an axis in which the support plate is configured to rotate around,
wherein the support plate moves from a third position to a fourth position when rotating the third gear about the fourth axis by a fourth angle,
wherein the fourth gear rotates about a fifth axis by a fifth angle, and
wherein the fourth gear is fixed to the connection member.

18. The display apparatus of claim 17, wherein the fourth angle is substantially equal to the fifth angle.

19. The display apparatus of claim 17, wherein the display unit includes a display screen, and a third direction in which the display screen is oriented at the third position is substantially parallel to a fourth direction in which the display screen is oriented at the fourth position.

20. A display apparatus comprising:
a plate;
a connection member disposed on the plate, the connection member having a first end connected to the plate; and
a display device disposed in a second end of the connection member,
wherein the plate forms a plane and is configured to rotate around a first axis in a first direction on the plane, and wherein the first axis is substantially perpendicular to the plane,
wherein the connection member is configured to rotate in a second direction around a second axis, wherein the second direction is different from the first direction, and wherein the second axis is substantially parallel to the first axis,
wherein the display device is configured to face a viewer at substantially the same direction when the plate rotates in the first direction.
